(19) United States
(12) Patent Application Publication
(10) Pub. No.: US 2016/0281216 A1
(43) Pub. Date: Sep. 29, 2016

(54) STRUCTURE HAVING STAIN-PROOFING AMORPHOUS CARBON FILM AND METHOD OF FORMING STAIN-PROOFING AMORPHOUS CARBON FILM

(71) Applicant: TAIYO YUDEN CHEMICAL TECHNOLOGY CO., LTD., Takasaki-shi, Gunma (JP)

(72) Inventor: Kunihiko Shibusawa, Takasaki-shi (JP)

(21) Appl. No.: 14/777,760

(22) PCT Filed: Mar. 18, 2014
(86) PCT No.: PCT/JP2014/057300

§ 371 Date: Sep. 17, 2015

(30) Foreign Application Priority Data
Mar. 19, 2013 (JP) 2013-056500
Sep. 27, 2013 (JP) 2013-201506
Dec. 19, 2013 (JP) 2013-262299

(51) Int. Cl. C23C 16/26; C23C 16/50

(52) U.S. Cl. CPC C23C 16/26; C23C 16/50

(57) ABSTRACT

An embodiment of the present invention provides a stain-proofing structure having a surface with excellent wear resistance. The structure includes a substrate and an amorphous carbon film formed on a surface of the substrate and having an isoelectric point in an acidic region.

### CROSS-REFERENCE TO RELATED APPLICATIONS

This application is based on and claims the benefit of priority from Japanese Patent Application No. 2013-056500 filed on Mar. 19, 2013, Japanese Patent Application No. 2013-201506 filed on Sep. 27, 2013, and Japanese Patent Application No. 2013-262299 filed on Dec. 19, 2013, the contents of which are hereby incorporated by reference in its entirety.

### TECHNICAL FIELD

The present invention relates to a structure having a stain-proofing amorphous carbon film and, in particular to a structure having an amorphous carbon film that suppresses adsorption of organisms.

### BACKGROUND

Sanitary pipes used in food processing facilities and clean pipes used for semiconductor manufacturing have highly smooth inner surface for preventing microbes and dust from adhering to the inner surface. For example, JIS-G3447 of Japanese Industrial Standards, which standardizes stainless steel pipes for the food industry, provides that the surface roughness of the stainless steel pipes be 1 μm or smaller (IS002037 of International Organization for Standardization provides for the same). Known techniques to achieve such a surface roughness include mechanical polishing such as buffing and chemical polishing such as electrobrightening provided on a stainless steel substrate, and wet plating provided on a surface of a substrate. For example, Japanese Patent Application Publication No. Hei 09-003655 discloses that mechanical polishing is provided to smoothen an inner surface of pipes for semiconductor manufacturing devices.

### SUMMARY

However, the surface of a substrate smoothened by mechanical polishing, chemical polishing, or wet plating tends to be roughened by friction or other causes; as a result, stain tends to adhere to the roughened portions. Therefore, it is necessary to keep the smoothened surface from being roughened by friction. Thus, a stain-proofing structure having a surface with excellent smoothness and wear resistance is demanded. The embodiments of the present invention provide stain-proofing structures having a surface with excellent wear resistance.

The Inventor has found that an amorphous carbon film formed on the smooth surface of a stainless steel substrate suppresses stain composed mainly of proteins such as microbes from adhering to the surface of the substrate. It has conventionally been thought that carbon materials such as an amorphous carbon film have a high affinity with organisms. For example, Japanese Patent Application Publication No. 2007-508816 discloses that a culture surface is covered with an amorphous carbon film such that neuron cells tend to adhere to the culture surface. Further, Japanese Patent Application Publication No. 2002-86178 discloses that carbon materials have an excellent affinity with organisms, and in particular, carbon fibers including oxygen-containing groups can increase adhesion of bacillus carboniphilus to the carbon fibers.

Thus, since it has been thought that carbon materials have a high affinity with organisms, no consideration has been given to application of carbon materials to members requiring high cleanness, e.g., pipes for food processing industry and clean pipes for semiconductor manufacturing. However, the Inventor has conducted various studies and experiments in view of the following. (1) An amorphous carbon film has a remarkably low surface activity since the dangling bond of carbon, which constitutes a main component of the amorphous carbon film, is terminated with a hydrogen atom. (2) The molecular structure of the amorphous carbon film is similar to those of artificial high molecular materials such as resins that allow less adhesion of microbes. (3) The isoelectric point of the amorphous carbon film lies within an acidic region as with many proteins causing stains. (4) The amorphous carbon film is hard and has a high wear resistance. As a result, the Inventor has found that an amorphous carbon film formed on a substrate surface allows less adhesion of stains composed mainly of microbes or proteins to the substrate surface. This finding led to the present invention.

The structure according to an embodiment of the present invention comprises a substrate and an amorphous carbon film formed on a surface of the substrate and having an isoelectric point in an acidic region.

A method of forming a stain-proofing amorphous carbon film according to an embodiment of the present invention comprises the steps of: preparing a substrate; and forming on a surface of the substrate an amorphous carbon film having an isoelectric point in an acidic region.

The embodiments of the present invention provide stain-proofing structures having a surface with excellent wear resistance.

### BRIEF DESCRIPTION OF THE DRAWINGS

FIG. 1 is a schematic cross-sectional view illustrating a structure according to an embodiment of the present invention.

FIG. 2 is a graph showing measured isoelectric points for Examples 3 and 4.

### DESCRIPTION OF EXAMPLE EMBODIMENTS

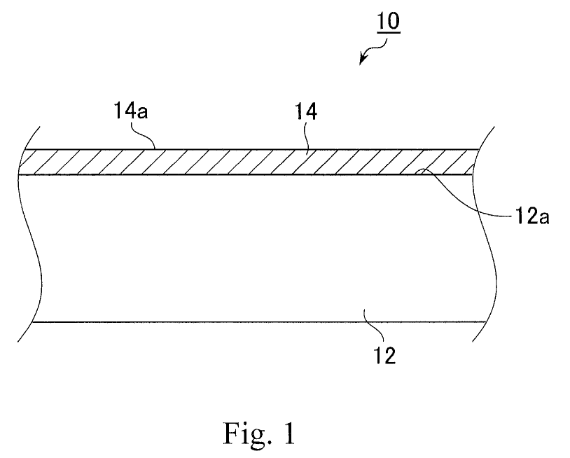

Various embodiments of the present disclosure will now be described with reference to the attached drawings. As shown in FIG. 1, a according to an embodiment of the present invention may include a substrate 12 and an amorphous carbon film 14. FIG. 1 schematically illustrates the structure 10 according to an embodiment of the present disclosure, and it should be noted that dimensional relationship is not accurately reflected in the drawing.

The structure 10 may be used as any member or a part thereof in, e.g., sanitary pipes and cutting apparatuses for food processing, clean pipes and interior finishing materials of clean rooms for semiconductor manufacturing, cooking utensils such as chopping blocks, tableware, and tablecloth, medical articles, screening apparatuses or filters in air conditioners. As will be described later, the structure 10 has an excellent stain-proofing quality, and thus can be used as an apparatus or member requiring high sanitariness and cleanness or as an apparatus or member used in an environment including stain such as protein that tend to adhere thereto. Applications of the structure 10 that will be described herein are mere examples. The structure 10 can be used for various applications not explicitly described herein.

A structure 10 in an embodiment can suppress stain caused by various biological molecules. Such biological molecules may include, e.g., natural biological molecules present in organisms such as animals, plants, and viruses, and produced or metabolized in the organisms. Further, such biological molecules may also include those artificially produced through modification of the natural biological molecules and those artificially designed independently of the natural biological molecules. As will be described later, the structure 10 in an embodiment may have a surface layer in which the isoelectric point is at pH of 6 or lower and lies within an acidic region, and may become negatively charged under a neutral condition with pH of about 7, producing an electric repulsive power to prevent stain. Therefore, the structure 10 may have a higher stain-proofing quality against biological molecules of which the surface becomes negatively charged under a neutral condition. The biological molecules may include biological materials such as proteins, nucleic acids, sugars, and lipids, and biological materials such as various organism cells and a part of organism cells.

The substrate 12 may be made of the following: a stainless steel such as SUS304; a bearing tool steel such as SKD; a sintered hard alloy such as tungsten carbide; steel; titanium; a soft metal such as magnesium, aluminum, tin, or brass or an alloy thereof; a precious metal such as gold, silver, copper, or platinum or an alloy thereof; a metal oxide such as alumina, zirconia, or titania; a ceramic such as a tile; earthenware; a resin such as polyester, polypropylene, polyethylene, polyvinyl chloride, or acryl; an engineering plastic such as an Ultem material; FRP; a carbon fiber material; paper (cellulose), silk, cotton, wool, or a mixture thereof; a rubber material used for a whipping tool or a putty tool; wood; cork; a semiconductor material such as silicon or germanium; and/or glass. The materials of the substrate 12 are not limited to those listed herein. On the surface of these materials, the substrate 12 may include a resin film made of polyimide, polyimide-amide, silicone, etc. The surface 12a of the substrate 12 may be smoothened to have a surface roughness in accordance with the application of the structure 10, so as to prevent adsorption of microbes or dust. For example, if the substrate 12 is made of stainless steel, the surface 12a may be polished to a desired surface roughness using conventional polishing methods including a mechanical polishing such as buffing and electrochemical polishing such as electrolytic polishing. As described above, JIS-G3447 of Japanese Industrial Standards provides that the surface roughness of the stainless steel for sanitary pipes be 1 μm or smaller. Thus, the substrate 12 according to an embodiment may be smoothened such that the surface roughness of the surface 12a is 1 μm or smaller. The surface roughness mentioned herein refers to an arithmetic mean roughness Ra measured in accordance with JIS-B0601 of Japanese Industrial Standards. If the substrate 12 is used as a structure of a sanitary pipe or a clean pipe, the surface 12a needs to be smoothened to have an extremely low surface roughness of 1 μm or smaller. In contrast, if the substrate 12 is used as a household cooking utensil or as a filter of an air conditioner for example, the surface 12a can be formed to be relatively rough (e.g., with a surface roughness of about 10 μm).

It has been reported that, when a stainless steel piece having a surface roughness of 1 μm or smaller is washed, the residual ratio of microbes adhering to the surface of the stainless steel piece is remarkably low (see, e.g., Keiko Yano, “Candida Endophthalmitis,” Kindai Publishing, “Clinicalness and Microbes,” Vol, 28, No. 2, 2001, pp. 201-206). It has been reported that disinfection activity of chlorine dioxide against Escherichia coli is degraded when there are recesses or projections in the surface having Escherichia coli adhering thereto. Thus, smoothening the surface 12a of the substrate 12 may enhance washing and disinfection effects against microbes adhering to the surface 12a (see, e.g., Kirschke, D. L. et al., “Pseudomonas aeruginosa and Serratia marcescens contamination associated with a manufacturing defect in bronchoscopes,” New Engl, J, Med., 348, 2003, pp. 214-220).

The amorphous carbon film 14 may be formed on the smoothened surface 12a of the substrate 12. The amorphous carbon film may be, e.g., a rigid film composed mainly of carbon and hydrogen and may be formed by various methods obvious to those skilled in the art. The amorphous carbon film 14 may be formed by various known dry processes including various plasma sputtering methods such as bipolar sputtering, tripolar sputtering, tetrapolar sputtering, magnetron sputtering, and facing target sputtering, various ion beam sputtering methods such as ion beam sputtering and ECR sputtering, various plasma CVD methods such as direct current (DC) plasma CVD method, low-frequency plasma CVD method, radio-frequency (RF) plasma CVD method, pulsed plasma CVD method, microwave plasma CVD method, atmospheric plasma method (e.g., dielectric-barrier discharge system), and subatmospheric plasma method, various ion plating methods using plasma such as direct current (DC) ion plating method, activated reactive evaporation (ARE) method, hollow cathode discharge (HCD) method, and radio-frequency (RF) excitation method, various ion plating methods using ion beams such as ion cluster beam evaporation (ICB) method, ion bean epitaxy (IBE) method, ion beam deposition (IBD) method, ion beam assisted deposition (IBAD) method, and ion vapor-deposition film formation (IVD) method, and combinations of these methods. For example, in the physical vapor deposition method (PVD method) using a solid Si target and carbon target, a substrate may be set in a film forming apparatus into which a sputtering gas (e.g., argon gas), a hydrocarbon-based material gas such as acetylene, and if necessary, a gas including hydrogen may be introduced at certain gas pressures and flow rates in a vacuum atmosphere, and the Si target and the carbon target may be subjected to sputtering, so as to form a structure according to an embodiment of the present invention on the substrate. This sputter gas may be mixed with oxygen (O), nitrogen (N), or a mixture gas thereof, so as to form an amorphous carbon film composed of a product of silicon and oxygen or nitrogen (e.g., SiO₂, SiN₂, etc.) by the reactive sputtering method. In the chemical vapor deposition method using a gas as a raw material (plasma CVD method), a work is set in a plasma CVD apparatus that is then evacuated with vacuum, and a hydrocarbon-based raw material gas including Si such as trimethylsilane, tetramethylsilane, tetraethoxysilane (TEOS) may be introduced in mixture with a hydrocarbon-based gas such as acetylene, so as to form an amorphous carbon film including Si. Further, the amorphous carbon film including Si formed on the substrate may be irradiated with oxygen plasma, nitrogen plasma, or plasma of a gas including at least one of oxygen and nitrogen such as the atmosphere, such that the amorphous carbon film may include both or one of oxygen and nitrogen. Further, in the amorphous carbon film according to an embodiment formed by irradiating a biased substrate 12 with a film material made into plasma with a high energy for deposition, components of the substrate 12 or components of various middle layers (particularly components of the surface layer) formed between the substrate 12 and the amorphous carbon film 14 may be agitated by the irradiation energy of the above plasma and mixed in the amorphous carbon film 14 to the extent within the purport of the present invention.

The amorphous carbon film 14 may additionally include at least one of oxygen, nitrogen, silicon, and silicon oxide, as required. Herein, the amorphous carbon film 14 may be referred to simply as an amorphous carbon film 14 even if it contains such an additive, unless the context requires otherwise. The amorphous carbon film 14 may be formed either directly on the substrate 12 or on an intermediate layer such as an amorphous carbon film containing silicon formed on the substrate 12. The intermediate layer may be formed by the plasma CVD method using a material gas such as trimethylsilane. Since the amorphous carbon film 14 can be formed by the plasma CVD method to be so thin and smooth that the surface 14a of the amorphous carbon film 14 may have almost the same surface roughness as the surface of the substrate 12 smoothened. For example, the amorphous carbon film 14 can have a surface roughness Ra of about 0.1 nm when it is formed by the plasma CVD method on Si (100) finished to a mirror surface. Thus, the amorphous carbon film 14 can be formed so as not to roughen the surface 14a of the structure 10. The amorphous carbon film 14 according to another embodiment may have a thickness of about 100 nm or larger depending on its application. In this case, the amorphous carbon film 14 can be formed continuously even if there are some indentations in the surface 12a of the substrate 12, thus preventing adhesion of stain to portions where the amorphous carbon film is not formed.

In an embodiment of the present invention, various intermediate layers can be placed between the substrate 12 and the amorphous carbon film 14 within the purport of the present invention. For example, in an embodiment of the present invention, it may be possible to form a plating film (not shown) having a high leveling tendency on the surface 12a of the substrate 12, and form an amorphous carbon film 14 on the plating film. This plating film may be formed by, e.g., noble metal plating such as electroless Ni plating, electrolytic Ni plating, electrolytic Cu plating, electroless Cu plating, electrolytic Cr plating, and electrolytic or electroless Au plating, Ag plating, and Ro plating. Beneath the plating layer may be formed a zinc substitution layer, a Pd substitution layer, etc. as necessary. Further, a plurality of such plating layers may be stacked to form a multilayer plating structure, or a composite alloy plating layer may be formed by, e.g., electrolytic Ni—Co plating. The amorphous carbon film formed by a plasma process may be deposited on the substrate using the electric field effect; therefore, such amorphous carbon film may have no leveling tendency on indentations in the surface of the substrate but rather emphasizes the indentations of the substrate. That is, the amorphous carbon film formed by a plasma process may tend to be deposited thicker on projections in the surface and thinner on recesses in the surface. If the surface roughness desired for the surface 14a of the structure 10 (the surface 14a of the amorphous carbon film 14) is not achieved by forming the amorphous carbon film 14 directly on the surface 12a of the substrate 12 smoothened by polishing such as mechanical polishing or plating, it may be possible to form a plating film as an intermediate layer on the surface 12a of the substrate 12 and form the amorphous carbon film 14 on the plating film so as to smoothen the surface 14a of the structure 10. For further example, it may also be possible to place in the surface layer of the substrate 12 an electrically conductive resin layer such as pyrrole or an oxide layer formed by the sol-gel method.

The amorphous carbon film 14 according to an embodiment may be formed to have an isoelectric point lower than that of the substrate 12. When the substrate 12 is composed of a metal or an alloy, the isoelectric point thereof typically is at pH of 8 or higher and lies within an alkaline region. The isoelectric point of a stainless steel (e.g., SUS316L) conventionally used in sanitary instruments, containers, and apparatuses is at pH of about 9.8 if the stainless steel is untreated after acetone cleaning and ethanol cleaning, and the isoelectric point of the same is at pH of about 9.0 if the stainless steel is heated for four hours at 150° C. after acetone cleaning and ethanol cleaning. Therefore, when the substrate 12 is composed of a metal or an alloy, the isoelectric point of the amorphous carbon film 14 should be at pH of 7 or lower under, e.g., a neutral condition. The isoelectric point of the amorphous carbon film 14 can be adjusted as necessary in accordance with the formulation of a material gas and the type of an additive included in the amorphous carbon film 14. For example, to move the isoelectric point more deeply in the acidic region, an ordinary amorphous carbon film composed of hydrogen and carbon should further include Si and then be irradiated with oxygen plasma.

Among various matters causing stain, those including microbes and hairs composed mainly of biological molecules such as proteins ordinarily have an isoelectric point thereof in the weak acidic region. Therefore, under a neutral condition with pH of about 7, carboxyl groups and phosphate groups in the surface of the matters are dissociated and are negatively charged, and thus may tend to be adsorbed onto the substrate 12, which may have an isoelectric point thereof in the alkaline region and may be positively charged under a neutral condition. On the other hand, the microbe cells may tend to adhere to the surface of the stainless steel piece positively charged under a neutral condition with pH of about 7. Thus, when the substrate 12 stands under a neutral condition, the substrate 12 may be positively charged, while the matters composed mainly of the biological molecules such as proteins may be negatively charged. Therefore, the matters may be adsorbed onto the substrate 12 and cause stain. In the embodiments of the present invention, the isoelectric point of the amorphous carbon film 14 may be lower than that of the substrate 12, thereby reducing the difference in polarity between the substrate 12 and the matter composed mainly of biological molecules such as protein and, as a result, suppressing the adsorption of the stain.

The term protein used herein may include proteins, polypeptides, and oligopeptides having any size, structure, and function, and examples thereof may include various proteins, enzymes, antigens, antibodies, lectin, or cell membrane receptors.

In an embodiment of the present invention, the amorphous carbon film 14 may be irradiated with oxygen plasma or nitrogen plasma so as to form functional groups such as carboxyl groups (—COOH) or hydroxyl groups (—OH) in the surface layer of the amorphous carbon film 14. When H⁺ ions in these functional groups are taken away by the hydroxide ions (OH⁻) present in an alkaline liquid, negatively ionized —COO— groups and —O— groups may be generated in the surface layer of the amorphous carbon film 14, and therefore, the surface layer of the amorphous carbon film may be negatively charged. Thus, carboxyl groups (—COOH) and hydroxide groups (—OH) generated in the surface layer of the amorphous carbon film 14 may cause the amorphous carbon film 14 to be further negatively charged, thereby further preventing adhesion of stain negatively charged.

In an embodiment of the present invention, the amorphous carbon film 14 may include matters having a lower isoelectric point than the amorphous carbon film 14 (e.g., Si (the isoelectric point of Si wafer lies in the acidic side beyond pH 3)). Examples of such matters include silicon (Si) and/or silicon oxide such as silicon dioxide. Silicon naturally generates hydroxyl groups upon contact with outside moisture or oxidation atmosphere. To introduce Si into the amorphous carbon film 14, a hydrocarbon-based material gas including Si such as trimethylsilane may be used in a process of forming the amorphous carbon film 14. In forming an amorphous carbon film including Si and oxygen, the amorphous carbon film 14 including Si may be irradiated with oxygen plasma, thereby preventing explosion caused by mixing introduction of oxygen-based gas into the hydrocarbon-based gas, enabling a large amount of oxygen to be safely included in the amorphous carbon film 14, and enabling a larger amount of functional groups (—OH) to be formed on the surface 14a of the amorphous carbon film 14 than in the case without irradiation with oxygen plasma. Also, the amount of oxygen introduced can be more readily adjusted than in the case where a hydrocarbon-based material gas previously including oxygen is used to form an amorphous carbon film including Si and oxygen.

Further, the amorphous carbon film 14 may be irradiated with oxygen plasma such that the interface portion thereof tightly adhered to the substrate 12 remains an amorphous carbon film 14 including Si providing high adhesiveness, while the surface layer portion (including the surface opposite to the substrate 12) serving as a functional interface with outside and not required to have adhesiveness with the substrate 12 may become an amorphous carbon film including large amounts of oxygen introduced by high energy plasma irradiation and Si including the functional groups mentioned above. In an embodiment, the amorphous carbon film 14 including Si may be irradiated with oxygen plasma such that transparency (optical transparency) of the portion into which the oxygen is introduced can be increased while keeping the ductility and the adhesiveness with the substrate 12 of the amorphous carbon film 14.

Additionally, such an amorphous carbon film including oxygen and Si may be formed on an adhesive layer (underlayer) composed of another amorphous carbon film that can adhere well to the substrate (e.g., an amorphous carbon film including Si for a metal substrate, or an amorphous carbon film composed only of carbon or mainly of hydrogen and carbon for a resin substrate) such that the amorphous carbon film including oxygen and Si can fixedly adhere to the substrate.

In the case where, e.g., the amorphous carbon film including Si is irradiated with oxygen plasma to form on a transparent resin substrate an amorphous carbon film including Si and oxygen that has a high transparency and a high wettability to water and has an isoelectric point biased to the acidic side due to a large number of functional groups formed (e.g., an amorphous carbon film including Si having a small thickness (e.g., about 10 nm or smaller) may be irradiated (injected) with oxygen plasma to the extent that oxygen plasma reaches the resin substrate such that the amorphous carbon film become highly transparent), it can be supposed that the amorphous carbon film including Si and oxygen has a poor adhesiveness to the resin substrate or ductility. In this case, another amorphous carbon film composed of hydrogen and carbon or composed of carbon may be formed first as an adhesive layer to such a small thickness as not to be colored (e.g., about several nanometers), and then the above amorphous carbon film including Si and oxygen may be formed on the adhesive layer.

The amorphous carbon film 14 including oxygen and Si formed by irradiating an amorphous carbon film 14 including Si with oxygen plasma includes more oxygen toward the surface thereof opposite to the substrate 12.

In an embodiment, the amorphous carbon film including Si is previously formed by a known plasma CVD method using a material gas such as tetramethylsilane, which is a hydrocarbon-based gas previously including Si, then the amorphous carbon film including Si is irradiated with oxygen plasma to form a structure, and this structure is subjected to an analysis by Fourier transform infrared spectroscopy (FT-IR analysis) (e.g., the amorphous carbon film is subjected to measurements for 32 times at a resolution of 8 (cm⁻¹) with HYPERION 3000 from Bruker as an analysis device by reflection absorption spectroscopy as an analysis method using microscopic ATR). In this case, it is estimated from the absorption spectra that the functional groups of the amorphous carbon film include Si—O bonds, because waveforms (absorption) peaked between 1200 (cm⁻¹) and 1300 (cm⁻¹) (or at about 1250 (cm⁻¹)) are detected for the above structure prepared by irradiating the amorphous carbon film including Si with oxygen plasma Such waveforms (absorption) are not detected in the case where the amorphous carbon film including Si and oxygen is formed by a known plasma CVD method wherein oxygen gas is mixed into a hydrocarbon-based material gas such as tetramethylsilane previously including Si.

Thus added silicon (Si) or silicon oxide may have a lower isoelectric point than the amorphous carbon film 14. Therefore, these additives may cause the surface layer of the amorphous carbon film 14 to be further negatively charged, thereby further preventing adhesion of stain negatively charged. In the case where, e.g., tetramethylsilane may be used as a plasma material gas to form an amorphous carbon film 14 including Si that is then irradiated with oxygen plasma to form an amorphous carbon film including Si and oxygen as described above, the Si content of the amorphous carbon film on, e.g., the “hydrogen-free criterion” wherein hydrogen in the amorphous carbon film is not detected and atomic composition is analyzed with ESCA (Electron Spectroscopy for Chemical Analysis) can be in a range from about 3 at. % to less than 20 at. %. As a result, the content of Si can be smaller than that of carbon, which may restrain reduction in inherent ductility and capability of preventing adhesion of soft metal of the amorphous carbon film composed of hydrogen and carbon. The content of oxygen applied through plasma irradiation may be at least 17 at. %; and the oxygen content on the “hydrogen-free criterion” may be at least 30 at. %, and more preferably 35 at. % or higher. When the content of oxygen is thus increased, the transparency (optical transparency) of the film can be further increased, and a large amount of functional groups such as hydroxyl groups (—OH) can be formed in the surface layer of the film.

For example, in the case where an amorphous carbon film 14 including Si in an embodiment that is irradiated with oxygen plasma, another amorphous carbon film irradiated with oxygen gas and/or a gas including oxygen and nitrogen made into plasma, and an amorphous carbon film 14 having a surface modified to be hydrophilic by a publicly known method are used in water or in contact with water or water vapor, a water layer (water film) may be formed on the surface which may further restrain adhesion of stain and fogging. Restraint of fogging on a substrate is effective for optical reading of a sample on the substrate (e.g., in surface treatment of highly transparent micro-channel such as μ-TAS, and surface treatment of analysis apparatus using a highly transparent capillary in an apparatus for analysis with electrophoresis), prevention of fogging and adhesion of foreign substance on a visible light lens, and surface treatment for preventing fogging on a mirror used for medical application or in an environment where it is desired to prevent adhesion of microbes. The above-described amorphous carbon film 14 having the surface thereof modified to be hydrophilic is also oleophilic, which can prevent stain by blurring adhering matters such as fingerprints composed mainly of fats and oils (that is broadly stain).

The amorphous carbon film 14 according to an embodiment may be formed such that the isoelectric point thereof is at pH of 6 or lower and lies within an acidic region. Thus, when the substrate 12 is used under a neutral condition, the substrate 12 and matters composed mainly of proteins may be both negatively charged and electrically repel each other. The repelling power may inhibit the adsorption of matters composed mainly of proteins on the substrate 12.

Thus, covering a substrate made of a metal having an isoelectric point lying within the neutral or alkaline region with an amorphous carbon film 14 having an isoelectric point lying within the acidic region may cause the isoelectric point of the surface layer of the substrate to be shifted toward the acidic side. For example, it is well known that mite allergen is negatively charged in water. A substrate made of a metal can be covered with such an amorphous carbon film so as to restrain adhesion of mites and microbes. In general, resin materials such as PET may be less subject to adhesion of microbes, but may suffer from adsorption of foreign substances due to static electricity. In contrast, a metal substrate covered with an amorphous carbon film 14 may have a lower coefficient of friction and thus produces less static electricity, and can be grounded relatively simply. Therefore, such a metal substrate may restrain adsorption of foreign substances more than those made of a resin material.

If a thin amorphous carbon film 14 is formed on a resin substrate to a thickness of several tens nanometers to one hundred and several tens nanometers, the amorphous carbon film, which has an excellent ductility, will not suffer from cracking even under about 3% uniaxial stretching. Thus, when covered with an amorphous carbon film, even a resin substrate, which has a high ductility and is intended to be used in various shapes deformed by external stresses and used in various applications and methods, can be modified in isoelectric point (zeta potential) and provided with functions of the amorphous carbon film (e.g., wear resistance, UV absorbing capacity (for preventing UV degradation of the resin substrate), gas permeable barrier quality for transmitting gases such as H₂, H₂O, and O₂).

The structure 10 according to one embodiment having an amorphous carbon film including Si irradiated with oxygen plasma may be supposed to have an isoelectric point which is the same as that of SiO₂ (quartz having an isoelectric point at pH of about 2.5) or lies in an acidic side region beyond the same. The negative potential (zeta potential) of the structure 10 ranging from the neutral region to the acidic region may be larger toward negative side than that of SiO₂ (about −50 mV to −70 mV near the alkaline side region from pH 7). That is, as compared to conventional stain-proofing structure composed of SiO₂, the structure 10 is stainproof for a larger pH range and thus can prevent stain more powerfully. To introduce oxygen into an amorphous carbon film including Si or an amorphous carbon film composed of hydrogen and carbon, the amorphous carbon film including Si may be plasma-irradiated with oxygen or a gas including oxygen (carbon dioxide gas, atmosphere, etc.), irradiated with a UV light, irradiated with ozone, or irradiated with active species formed from atmosphere through corona discharge or atmospheric pressure plasma.

The structure 10 according to one embodiment having an amorphous carbon film including Si and irradiated with oxygen plasma may have an isoelectric point in further acidic side region beyond the isoelectric points of resins such as PET (the isoelectric point thereof has a pH of about 4; and the minimum zeta potential at pH of about 8 to 9 is about −70 mV) and an amorphous carbon film composed of hydrogen and carbon and not including Si. Therefore, the structure 10 can prevent adhesion of stain over a wide region covering a further acidic region.

The structure 10 formed by irradiating an amorphous carbon film including Si according to an embodiment with oxygen plasma and an amorphous carbon film composed of hydrogen and carbon and not including Si has a minus zeta potential over a wider pH range than resins such as PET, and this minus potential is large; therefore, the structure 10 may have a larger repellence against stain negatively charged.

There has been known a microchip (also referred to as MEMS or μTAS (micro total analysis system)) prepared by laser machining, etching, or other micromachining technology and designed to perform chemical reaction, separation, analysis, etc, of a liquid reagent including protein or blood on a substrate made of Si, glass (SiO_{X}), a resin, or a metal, a channel, or a circuit. In such a device as the microchip wherein a liquid is placed into a microchannel for analysis or inspection, the surface of the channel may be treated to be hydrophilic such that the liquid sample spreads well and fills the channel. Conventionally, SiO₂ is used in the surface layer of the above-mentioned channel because it is a hydrophilic, inorganic, and stable material. Substrates of microchips are often made of glass, but since glass is expensive, there have been a high demand for microchips having a substrate made of a low-cost and disposable resin material.

If the surface layer of such a microchip is covered with an amorphous carbon film, an amorphous carbon film including Si and having oxygen introduced thereinto, or an amorphous carbon film modified such that the isoelectric point thereof is biased to the acidic side, negatively charged biological samples can be prevented from being adhered to the channel because the surface potential of these amorphous carbon films are negative. Further, the microchip can be provided with excellent properties of the amorphous carbon film such as surface smoothness, wear resistance, stability, corrosion resistance, gas barrier quality, and ductility.

An amorphous carbon film may adhere very well to a resin substrate. This is supposed to be because an amorphous carbon film has composition similar to that of resins composed mainly of hydrogen and carbon. Further, as described above, the amorphous carbon film may have excellent ductility and thus may be adaptable to deformation, thermal expansion, and contraction of the resin substrate, thereby maintaining tight adhesion to the resin substrate.

The amorphous carbon film including Si and having oxygen introduced thereinto may be formed by the following methods: e.g., the method wherein oxygen or a gas including oxygen may be mixed at a certain ratio with a hydrocarbon-based gas including Si such as tetramethylsilane gas to form an amorphous carbon film including Si and oxygen; the method wherein a hydrocarbon-based gas previously including oxygen at a certain ratio may be used; and a method wherein a hydrocarbon-based gas including Si such as tetramethylsilane gas may be used to previously form an amorphous carbon film including Si which is then plasma-irradiated with oxygen or a gas including oxygen. In the case where oxygen or a gas including oxygen may be mixed at a certain ratio with a hydrocarbon-based gas including Si such as tetramethylsilane gas to form an amorphous carbon film including Si and oxygen, the film can be made transparent, which facilitates observation of a channel of a microchip.

The amorphous carbon film irradiated with oxygen and/or nitrogen made into plasma, the amorphous carbon film including Si, and the amorphous carbon film including Si having oxygen and/or nitrogen introduced thereinto may provide adhesion to a coupling agent fixed with hydroxyl groups in the surface layer of a substrate by hydrogen bonding or condensation reaction. For example, any of the above-mentioned amorphous carbon films may be formed on a desired portion of the microchip to tightly fix a coupling agent (e.g., a silane coupling agent, or a coupling agent based on titanate, aluminate, or zirconate). Therefore, for example, a fluorine-containing silane coupling agent may be fixed on a desired portion of any of the above-mentioned amorphous carbon films to modify this portion to have a water-and-oil repellent surface.

An amorphous carbon film, which is electrically insulating, exhibits electrical conductivity when, e.g., irradiated with a laser beam and heated, or heated in an oxygen-free atmosphere with such an energy that does not deplete the film. For example, in a microchip according to an embodiment of the present invention (a microchannel having an amorphous carbon film formed thereon) formed on a semiconductor substrate made of Si or an insulator such as glass, at least a part of the amorphous carbon film may be irradiated with a laser beam in a wiring form, so as to form electric wiring (circuit) composed of the amorphous carbon film modified to be electrically conductive in the wiring form. For example, a laser beam that can be applied to an extremely small area having a diameter of several micrometers to several tens of micrometers can be applied in a wiring form to form microwires of the amorphous carbon film made electrically conductive and extending separately at one end and the other end of the microchannel. These conductive portions of the amorphous carbon film can be supplied with electricity or subjected to voltage. Thus, there is no need of providing the formed microchannel with masking in the form of necessary electric microwires with high positional accuracy and newly forming electric wiring by sputtering using other electrically conductive materials as electric wiring materials.

In another embodiment wherein the substrate is made of a conductor such as a metal, the amorphous carbon film formed on the substrate is insulating; therefore, only the surface layer in the thickness direction of the amorphous carbon film may be modified to be electrically conductive, thereby to form the electric wiring (circuit) in the above-mentioned wiring form. Thus, in a microchip according to an embodiment having a microchannel formed on an insulating amorphous carbon film, desired portions of the amorphous carbon film can be made electrically conductive (provided with electric wiring (circuit)), thereby facilitating, e.g., separation of a sample in the microchannel by capillary electrophoresis and modification and transfer of a sample.

Since the amorphous carbon film 14 is hard and wear resistant, it can prevent roughening of the smoothened surface 12a of the substrate 12. As a result, adsorption of stain onto the structure 10 due to roughness can be restrained. Thus, the amorphous carbon film 14 can maintain smoothness of the structure 10 and repel substances composed mainly of microbes or proteins, thereby improving the stainproof property of the structure 10 particularly against substances composed mainly of microbes or proteins.

In an embodiment of the present invention, the structure 10 having the amorphous carbon film 14 formed thereon may be subjected to UV irradiation or ozone cleaning for further sterilization. When the amorphous carbon film 14 includes Si or a silicon oxide such as SiO₂, the structure 10 may have high resistance against oxidation caused by UV irradiation or ozone cleaning.

In an embodiment of the present invention, the amorphous carbon film 14 may include a silicon oxide such as SiO₂ or the amorphous carbon film 14 may be irradiated with oxygen plasma and/or nitrogen plasma, thereby increasing the water wettability of the amorphous carbon film 14. Thus, the surface 14a of the structure 10 can be more readily cleaned with water. Also, bactericidal agent such as chlorine dioxide can be well spread on the surface 14a, which facilitates sterilization with a sterilizer. Further, samples such as water and aqueous solution can be well spread and readily supplied into the microchip or the microchannel having formed thereon the amorphous carbon film according to an embodiment.

One way to make samples such as water and aqueous solution including biological molecules to be analyzed spread on the surface of the microchip or the microchannel is, e.g., to form a film exhibiting strong hydrophilicity such as a photocatalytic film including TiO₂ or ZnO. However, a photocatalytic film may also unfavorably produce an active substance (e.g., active oxygen originated from superoxide radical anion) that can dissolve or attack biological samples and a substrate made of a polymeric material such as a resin. The amorphous carbon film 14 in an embodiment may prevent adhesion of biological molecule sample while restricting the impact on the biological molecule sample and the substrate caused by attack on the biological molecules, and the amorphous carbon film 14 can form a hydrophilic surface. Accordingly, the amorphous carbon film is suited to surface treatment in applications wherein impact on the biological molecules and the substrate in the microchannel is unfavorable.

In an embodiment of the present invention, the amorphous carbon film 14 may be formed in a polymer form to increase ductility thereof.

The structure 10 in an embodiment of the present invention can be applied to medical items. For example, pH of blood, lymph, tissue fluid, and cell fluid are normally maintained at pH of 7.4±0.05 by homeostasis. It is well known that most mammals maintain blood thereof at pH of about 7.4. In such an environment having pH of about 7.4, an amorphous carbon film may exhibit a negatively high zeta potential of about −100 mV and more strongly restrain adhesion of microbes also negatively charged.

For example, when the amorphous carbon film 14 in an embodiment of the present invention includes Si, oxidation of Si occurs when Si contacts with oxidative atmosphere including the atmosphere and water and thus Si—OH groups are formed in the surface layer. When the film is irradiated with UV or ozone, formation of the Si—OH groups are ensured. Accordingly, when the amorphous carbon film 14 in an embodiment is formed on a surface layer substrate of a medical instrument repeatedly subjected to UV sterilization and ozone sterilization, oxidizing condition in the surface of the substrate can be efficiently improved and maintained (low zeta potential or hydrophilicity are maintained) simultaneously with sterilization of the medical instrument. Further, particularly the amorphous carbon film including Si and O may the following features. (1) Since the isoelectric point of the film is biased to the acidic side, the film may permit general use of cleaning liquids and additives added therein having a wide range of pH values. (2) The film may be resistant to UV irradiation, ozone irradiation, and heating. (3) There is less risk of removal because the film has strong adhesion to the substrate. (4) The film can be cleaned well because of high water wettability. (5) The film may cause less damage on a mating member because of a low coefficient of friction and the smoothness of the surface. The film can be effectively applied to medical (surgical) instruments such as surgical knives, sewing needles, scissors, guide wires, pliers, pipe portions of endoscopes, lens portions of endoscopes, injection needles, infusion bags, and wound retainers, medical articles such as medical packing materials, medical equipment, medical apparatuses, and interior finishing materials and equipment of a medical treatment room, and research, development, and production of such medical articles and medical raw materials of pharmaceuticals. When such medical articles are disposable or reusable, it may be possible to restrain adhesion of harmful microbes and pathogens to the surface layers of the above-mentioned medical instruments, etc, and restrain secondary infection of diseases to outside after use of the medical instruments, etc. on patients.

When an amorphous carbon film is modified to include Si and oxygen, the isoelectric point thereof is biased to the acidic side, and a larger negative zeta potential is obtained in the same pH environment. Therefore, various amorphous carbon films having various isoelectric points can be formed on desired portions of the same substrate such that adsorption and prevention of adhesion of objects are possible in accordance with the surface potentials different for the various amorphous carbon films. That is, various amorphous carbon films having different isoelectric points and zeta potentials may be formed on the same substrate for selection and screening of the objects.

Likewise, an amorphous carbon film or a modified amorphous carbon film may be tentatively formed on the substrate in a film form and then removed, and thus obtained separate amorphous carbon film (made into powder or particles) can be used as a dispersant or a dispersion media. Removal of an amorphous carbon film formed on a substrate for obtaining a separate film can be achieved relatively simply as follows: e.g., an amorphous carbon film may be formed in a film form on a substrate made of an aluminum alloy, and then the aluminum substrate may be melted; or an amorphous carbon film may be formed on a substrate which does not adhere well to the amorphous carbon film such as an electrolytic Ni plating film, and then a major heat shock is applied by, e.g., quenching in cold water. Thus, in the case where an amorphous carbon film is formed on a substrate and then removed as a separate film (powder) in water, the isoelectric point of the amorphous carbon film may be biased to the acidic side such that the negative zeta potential at the surface of each pH region is larger than that of a normal amorphous carbon film. As a result, repulsive power may be increased in the separate amorphous carbon film (powder), and thus condensation may be less likely to occur, facilitating draw of the separate amorphous carbon film (powder) dispersed. The separate amorphous carbon film (powder) thus drawn may be mixed and kneaded with a base material such as a resin and thereby serve as a structure according to an embodiment of the present invention providing the surface of a substrate with stainproof property and wear resistance.

In an embodiment of the present invention, the zeta potential at the surface of the amorphous carbon film can be controlled to prevent or control the adsorption of not only polarized biological molecules but polarized surfactants, etc.

### EXAMPLES

### Example 1

A substrate of a stainless steel (SUS304) was prepared to a surface roughness Ra of 0.077 μm, and a size of 30 mm by 7 mm and a thickness of 0.1 mm. This substrate was subjected to ultrasonic cleaning for 15 minutes in a stainless tray filled with isopropyl alcohol (IPA). Next, the stainless steel substrate cleaned was placed on a sample table of a reaction container of a high pressure DC pulse plasma CVD apparatus, and the reaction container was evacuated to 3×10⁻³ Pa. Then, trimethylsilane was introduced into the reaction container at a flow rate of 30 SCCM to a gas pressure of 2 Pa, while applying a voltage of −4.5 kV to form an amorphous carbon film including silicon (an intermediate layer) for five minutes. Next, on this intermediate layer was formed for 15 minutes an amorphous carbon film by using acetylene as a material gas at a gas flow rate of 40 SCCM and applying a voltage of −5 kV under conditions of a pulse frequency of 10 kHz, a pulse width of 10 μs, and a gas pressure of 2 Pa. Next, the sample was turned over and again set on the sample table, and amorphous carbon films were also formed on the bottom surface of the sample in the same process as described above. Thus, the sample for Example 1 was obtained.

### Example 2

As with Example 1, a substrate of a stainless steel (SUS304) was prepared to a size of 30 mm by 7 mm and a thickness of 0.1 mm. This substrate was subjected to ultrasonic cleaning for 15 minutes in a stainless tray filled with isopropyl alcohol (IPA). Next, the stainless steel substrate cleaned was placed on a sample table of a reaction container of a high pressure DC pulse plasma CVD apparatus, and the reaction container was evacuated to 3×10⁻³ Pa. Then, trimethylsilane was introduced into the reaction container at a flow rate of 30 SCCM to a gas pressure of 2 Pa, while applying a voltage of −4.5 kV to form an amorphous carbon film including silicon (an intermediate layer) for five minutes. Next, on this intermediate layer was formed for 15 minutes an amorphous carbon film by using acetylene as a material gas at a gas flow rate of 40 SCCM and applying a voltage of −5 kV under conditions of a pulse frequency of 10 kHz, a pulse width of 10 μs, and a gas pressure of 2 Pa. Next, nitrogen gas was introduced into the reaction container at a flow rate of 30 SCCM to a gas pressure of 1.5 Pa, while applying a voltage of −4 kV to irradiate the sample with nitrogen plasma for five minutes such that the amorphous carbon film on the sample surface includes nitrogen. Next, the sample was turned over and again set on the sample table, and amorphous carbon films including nitrogen were also formed on the bottom surface of the sample in the same process as described above. Thus, the sample for Example 2 was obtained.

### Comparative Example 1

As with Examples 1 and 2, a substrate of a stainless steel (SUS304) was prepared to a size of 30 mm by 7 mm and a thickness of 0.1 mm. This bare stainless steel piece was taken as Comparative Example 1.

Microbe Adhesion Test

Next, adhesion test of Escherichia coli to the sample surfaces of the Examples 1 and 2 and Comparative Example 1 obtained as above was conducted. First, Escherichia coli (NBRC3301(K12)) was cultured at 30° C. in a PY liquid medium (polypepton 10 g, yeast extract 2 g, MgSO⁴.7H₂O 1 g, DW 1 l, pH 7.0). Next, the bacterial cells of Escherichia coli collected were suspended in saline. Each of this suspension diluted and the samples of Examples 1 and 2 and Comparative Example 1 was placed into a microtube in 2 ml and was incubated for two hours while being agitated slowly at room temperature. Thus, Escherichia coli was adhered to the surfaces of the samples of Examples 1 and 2 and Comparative Example 1.

Next, the samples of Examples 1 and 2 and Comparative Example to which Escherichia coli was adhered were subjected to buffer cleaning. The count of Escherichia coli present on the surface of the samples of Examples 1 and 2 and Comparative Example 1 cleaned were measured by bioluminescence method (luciferin-luciferase reaction system). More specifically, ATP is extracted from cells of Escherichia coli adhered to the surfaces of the samples of Examples 1 and 2 and Comparative Example 1, and the extracted ATP was reacted with a bioluminescence reagent (a Lucifell HS set (model number: 60315) from Kikkoman Corporation). The amount of luminescence emitted by the reaction was measured using a microplate reader (1420 ARVOsx multilevel counter from Wallac, Inc.), and the luminescence intensity of ATP was determined from the measured amount of luminescence. The viable count of Escherichia coli was estimated from the measured amount of ATP based on a standard curve indicating the relationship between the luminescence intensity of ATP and the viable count of Escherichia coli generated by the plate culture colony count method.

The count of Escherichia coli thus estimated was 171,677 for Example 1, 132,390 for Example 2, and 648,043 for Comparative Example 1. Thus, it was observed that the counts of Escherichia coli present on the surface of Examples 1 and 2 of the present invention are significantly smaller than the count of Escherichia coli present on the surface of Comparative Example 1.

Next, adhesion test of denitrificans to the sample surfaces of the Examples 1 and 2 and Comparative Example 1 was conducted. First, denitrificans (Pseudomonas stutzeri NBRC14165) was cultured in a PY liquid medium at 30° C. Next, the bacterial cells of denitrificans collected were suspended in the PY liquid medium. Each of this suspension diluted and the samples of Examples 1 and 2 and Comparative Example 1 was placed into a microtube in 2 ml and was incubated for two hours while being agitated slowly at room temperature. Thus, denitrificans was adhered to the surfaces of the samples of Examples 1 and 2 and Comparative Example 1.

Next, the samples of Examples 1 and 2 and Comparative Example to which denitrificans was adhered were subjected to buffer cleaning. As with the example for Escherichia coli described above, the count of denitrificans present on the surface of the samples of Examples 1 and 2 and Comparative Example 1 cleaned were measured by bioluminescence method (luciferin-luciferase reaction system). The count of denitrificans thus estimated was 47,255 for Example 1, 50,498 for Example 2, and 195,705 for Comparative Example 1. Thus, it was observed that the counts of denitrificans present on the surface of Examples 1 and 2 of the present invention are significantly smaller than the count of denitrificans present on the surface of Comparative Example 1.

Measurement of Isoelectric Point of Amorphous Carbon Film

Next, the isoelectric point of an amorphous carbon film was measured. First, a rectangular Si (100) plate was prepared to a size of 30 mm by 40 mm and a thickness of about 0.6 mm. This substrate was subjected to ultrasonic cleaning in isopropyl alcohol (IPA) and then cleaned with Ar gas plasma, and an amorphous carbon film composed of hydrogen and carbon was formed on a gloss surface of the substrate to a thickness of about 500 nm by a known plasma CVD method using acetylene as a raw material gas. This amorphous carbon film was taken as Example 3. Further, as with Example 3, the substrate was subjected to ultrasonic cleaning and Ar gas plasma cleaning, an amorphous carbon film including Si was formed to a thickness of about 500 nm by a known plasma CVD method using tetramethylsilane gas as a raw material gas, then the tetramethylsilane gas was exhausted, and oxygen was applied via oxygen gas plasma. This amorphous carbon film was taken as Example 4. The application of oxygen gas plasma was kept for 10 minutes at a flow rate of oxygen gas of 30 SCCM, a gas pressure of 1.5 Pa, and an applied voltage on the substrate of −3.5 kVp.

Next, the isoelectric points (zeta potentials) for Examples 3 and 4 were measured. The measurement was conducted by the following known measurement method.

Measurement apparatus: zeta potential measurement apparatus SurPASS (from Anton Paar Japan K.K.)

Measurement cells: clump cells

Measurement temperature: room temperature Measurement pH: 9→2.5 (neutral→acidic) (The pH value was changed at the decrement of 0.5.)

pH titrant: hydrochloric acid in 0.1 mol/l

Electrolyte: potassium chloride aqueous solution in 0.001 mol/l

Number of measurements: one time

Measurement principle: streaming current method

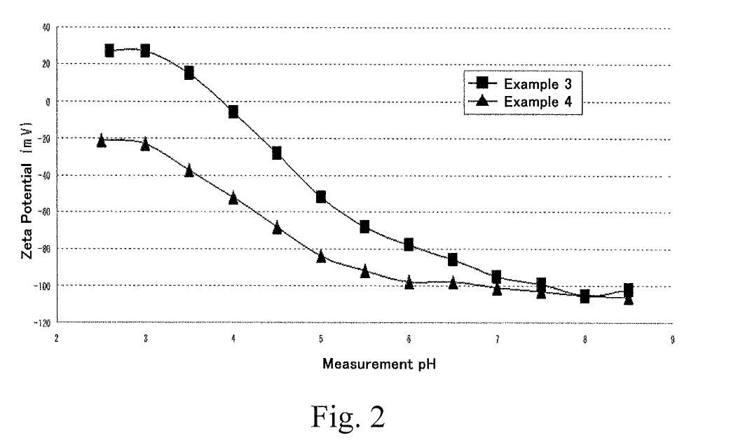

FIG. 2 shows the measurement result. The isoelectric point for Example 3 (wherein an amorphous carbon film composed of hydrogen and carbon was formed) was observed around pH 3.8. In contrast, the isoelectric point for Example 4 (wherein the amorphous carbon film composed of hydrogen and carbon further included Si and O) was observed in the acidic side beyond pH 2.5. As shown in the figure, the zeta potentials for Example 3 were −5 mV at pH 4, −50 mV at pH 5, −80 mV at pH 6, −95 mV at pH 7, and −105 mV at pH 8. The zeta potentials for Example 4 were −50 mV at pH 4, −85 mV at pH 5, −98 mV at pH 6, −100 mV at pH 7, and −105 mV at pH 8. Thus, it was observed that the amorphous carbon film modified to include, e.g., Si, and oxygen had an isoelectric point biased to the acidic side. Further, it was observed that larger negative zeta potentials can be obtained in an environment having the same pH value.

What is claimed is:

1. A structure comprising:
a substrate;
an amorphous carbon film formed on a surface of the substrate and having an isoelectric point in an acidic region.

2. The structure of claim 1 wherein the amorphous carbon film has an isoelectric point at pH of less than 4.

3. The structure of claim 1 wherein the substrate is smoothened to a surface roughness of 1 μm or less measured in conformity to Japanese Industrial Standard JIS-B0601.

4. The structure of claim 1 wherein the amorphous carbon film has a lower isoelectric point than the substrate.

5. The structure of claim 1 wherein the substrate comprises Si or a resin.

6. The structure of claim 1 wherein the amorphous carbon film comprises another material having a lower isoelectric point than the amorphous carbon film.

7. The structure of claim 1 wherein the amorphous carbon film comprises at least one of Si, N, and O.

8. The structure of claim 7 wherein the amorphous carbon film comprises Si and O, and Si content on a hydrogen-free criterion is less than 20 at. %.

9. The structure of claim 7 wherein the amorphous carbon film comprises Si and O, and O content is 17 at. % or more.

10. The structure of claim 7 wherein the amorphous carbon film comprises Si and O in a surface layer portion including a surface opposite to the substrate.

11. The structure of claim 7 wherein the amorphous carbon film comprises more oxygen toward a surface opposite to the substrate.

12. The structure of claim 7 wherein the amorphous carbon film is formed by applying plasma including oxygen to a surface of an amorphous carbon film including Si.

13. The structure of claim 1 having an intermediate layer between the substrate and the amorphous carbon film.

14. The structure of claim 1 wherein the amorphous carbon film comprises a plurality of amorphous carbon films each having a different isoelectric point.

15. A medical article comprising the structure of claim 1.

16. The medical article of claim 15 wherein the amorphous carbon film in the structure includes Si.

17. A microchip comprising the structure of claim 1.

18. The microchip of claim 17 wherein at least part of the amorphous carbon film is modified to be electrically conductive by heating.

19. A method of forming a stain-proofing amorphous carbon film, comprising the steps of:
preparing a substrate; and
forming on a surface of the substrate an amorphous carbon film having an isoelectric point in an acidic region.
